(19) United States
(12) Patent Application Publication
(10) Pub. No.: US 2016/0205776 A1
(43) Pub. Date: Jul. 14, 2016

(54) COVER FILM WITH HIGH DIMENSIONAL STABILITY AND MANUFACTURING METHOD OF FLEXIBLE PRINTED CIRCUIT BOARD

(71) Applicant: Taiflex Scientific Co., Ltd., Kaohsiung (TW)

(72) Inventors: Hsiu-Chu Wu, KAOHSIUNG (TW); Ching-Wen Yu, KAOHSIUNG (TW); Wen-Chien Chen, KAOHSIUNG (TW); Wu-Ying Su, KAOHSIUNG (TW); Wei-Yuan Huang, KAOHSIUNG (TW); Meng-Cheng Tsai, KAOHSIUNG (TW); Chi-Sheng Hung, KAOHSIUNG (TW)

(21) Appl. No.: 14/620,197

(22) Filed: Feb. 12, 2015

(30) Foreign Application Priority Data
Jan. 13, 2015 (TW) 104101091

(51) Int. Cl. H05K 1/03; H05K 3/46

(52) U.S. Cl. CPC H05K 1/0393; H05K 3/46; H05K 2201/0145; H05K 2201/0154; H05K 2201/0158

(57) ABSTRACT

A cover film with high dimensional stability includes an insulation film, a first adhesive layer, and a carrier. A first side of the first adhesive layer is connected to a first surface of the insulation film, and a second side of the first adhesive layer is configured to adhere to at least one metal conductor of a flexible printed circuit board. The carrier includes a supporting film and a second adhesive layer. A first side of the second adhesive layer is connected to the supporting film, and a second side of the second adhesive layer is adhered to a second surface of the insulation film, wherein bonding strength of the second adhesive film is smaller than bonding strength of the first adhesive film.

### BACKGROUND OF THE INVENTION

1. Field of the Invention

The present invention relates to a cover film with high dimensional stability and a manufacturing method of flexible printed circuit board, and more particularly, to a cover film with high dimensional stability and a manufacturing method of flexible printed circuit board capable of improving dimensional stability and production efficiency.

2. Description of the Prior Art

With the progress of related technology, thinner electronic devices are developed according to demands. In order to reduce thickness of an electronic device, internal electronic components of the electronic device must also be thinner. The electronic device usually comprises a flexible printed circuit board connected to different electronic components for signal transmission. Generally, the flexible printed circuit board is formed by adhering an insulation film to metal wires. In order to reduce thickness of the flexible printed circuit board, thickness of the insulation film must also be decreased. However, when the thickness of the insulation film of the flexible printed circuit board is decreased, the insulation film may be easily deformed due to weakened mechanical strength, so as to cause dimension error, which further increases difficulty to align a positioning hole of the insulation film to a positioning jig. Moreover, it is more difficult for operators to precisely attach a thinner insulation film on the metal wires, so as to decrease production efficiency and yield of the flexible printed circuit board.

### SUMMARY OF THE INVENTION

The present invention provides a cover film with high dimensional stability and a manufacturing method of flexible printed circuit board capable of improving dimensional stability and production efficiency, in order to solve problems of the prior art.

The cover film with high dimensional stability of the present invention comprises an insulation film, a first adhesive layer, and a carrier. A first side of the first adhesive layer is connected to a first surface of the insulation film, and a second side of the first adhesive layer is configured to adhere to at least one metal conductor of a flexible printed circuit board. The carrier comprises a supporting film and a second adhesive layer. A first side of the second adhesive layer is connected to the supporting film, and a second side of the second adhesive layer is adhered to a second surface of the insulation film, wherein bonding strength of the second adhesive film is smaller than bonding strength of the first adhesive film.

In an embodiment of the present invention, the carrier is removable from the second surface of the insulation film.

In an embodiment of the present invention, thickness of the insulation film is smaller than or equal to 12.5 μm.

In an embodiment of the present invention, thickness of the supporting film is greater than or equal to 25 μm.

In an embodiment of the present invention, the cover film further comprises a release film covering on the second side of the first adhesive layer.

In an embodiment of the present invention, the insulation film is made of a material selected from a group consisting of a polyimide resin, a polyester resin, a polyethylene terephthalate resin, a polyethylene resin, a polypropylene resin, a polyvinyl chloride resin, a polystyrene resin, and a polycarbonate resin.

In an embodiment of the present invention, the supporting film is made of a material selected from a group consisting of a polyimide resin, a polyester resin, a polyethylene terephthalate resin, a polyethylene resin, a polypropylene resin, a polyvinyl chloride resin, a polystyrene resin, and a polycarbonate resin.

In an embodiment of the present invention, the first adhesive layer is formed by coating an acrylic acid resin, an epoxy resin, a phenol formaldehyde resin or a polyester resin on the first surface of the insulation film.

In an embodiment of the present invention, the second adhesive layer is formed by coating an acrylic acid resin, a polymerized siloxanes resin, a rubber resin, an ethylene vinyl acetate (EVA) resin, a polyurethane resin or a fluorine resin on the supporting film.

The manufacturing method of flexible printed circuit board of the present invention comprises providing a cover film, wherein the cover film comprises an insulation film, a first adhesive layer, and a carrier, a first side of the first adhesive layer is connected to a first surface of the insulation film, the carrier comprises a supporting film and a second adhesive layer, a first side of the second adhesive layer is connected to the supporting film, and a second side of the second adhesive layer is adhered to a second surface of the insulation film; adhering a second side of the first adhesive layer to at least one metal conductor; and after adhering the second side of the first adhesive layer to the at least one metal conductor, removing the carrier from the second surface of the insulation film.

In an embodiment of the present invention, the cover film further comprises a release film covering on the second side of the first adhesive layer, and the manufacturing method further comprises removing the release film before adhering the second side of the first adhesive layer to the at least one metal conductor.

In contrast to the prior art, the cover film of the flexible printed circuit board of the present invention comprises a carrier to support the insulation film, in order to increase overall mechanical strength. Therefore, dimensional stability of the insulation film is improved to solve the deformation problem induced by thinner thickness. Moreover, when manufacturing the flexible printed circuit board, since the insulation film is supported by the carrier, operators can hold the insulation film steady to attach the insulation film to the metal conductor rapidly and precisely. As a result, the cover film of the present invention is capable of improving the production efficiency and yield rate of the flexible printed circuit board.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a cover film with high dimensional stability of the present invention.

FIG. 2 is a diagram illustrating a manufacturing method of the cover film with high dimensional stability of the present invention.

FIG. 3 is a diagram illustrating a manufacturing method of a flexible printed circuit board of the present invention.

FIG. 4 is a flowchart showing the manufacturing method of the flexible printed circuit board of the present invention.

### DETAILED DESCRIPTION

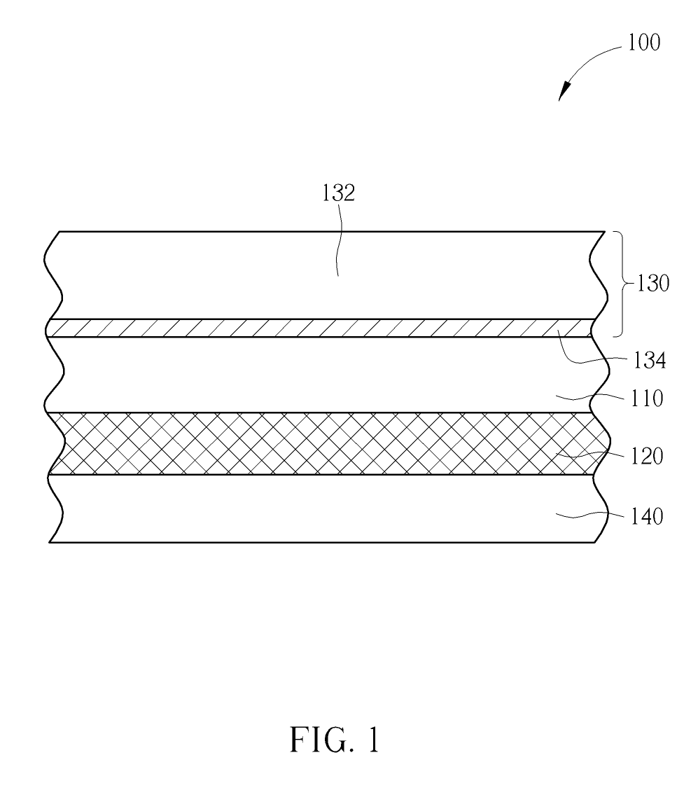

Please refer to FIG. 1. FIG. 1 is a diagram showing a cover film with high dimensional stability of the present invention. As shown in FIG. 1, the cover film 100 with high dimensional stability of the present invention comprises an insulation film 110, a first adhesive layer 120, and a carrier 130. The insulation film 110 can be made of a material selected from a group consisting of a polyimide resin, a polyester resin, a polyethylene terephthalate resin, a polyethylene resin, a polypropylene resin, a polyvinyl chloride resin, a polystyrene resin, and a polycarbonate resin. A first side (upper side) of the first adhesive layer 120 is connected to a first surface (lower surface) of the insulation film 110, and a second side (lower side) of the first adhesive layer 120 is configured to adhere to at least one metal conductor of a flexible printed circuit board. The first adhesive layer 120 can be formed by coating a material, which is selected from a group consisting of an acrylic acid resin, an epoxy resin, a phenol formaldehyde resin and a polyester resin, on the first surface of the insulation film 110. The carrier 130 comprises a supporting film 132 and a second adhesive layer 134. The supporting film 132 can be made of a material selected from a group consisting of a polyimide resin, a polyester resin, a polyethylene terephthalate resin, a polyethylene resin, a polypropylene resin, a polyvinyl chloride resin, a polystyrene resin, and a polycarbonate resin. A first side (upper side) of the second adhesive layer 134 is connected to the supporting film 132, and a second side (lower side) of the second adhesive layer 134 is adhered to a second surface (upper surface) of the insulation film 110. The second adhesive layer 134 can be formed by coating a material, which is selected from a group consisting of an acrylic acid resin, a polymerized siloxanes resin, a rubber resin, an ethylene vinyl acetate (EVA) resin, a polyurethane resin and a fluorine resin, on the supporting film 132. In order to allow the carrier 130 to be removed from the second surface of the insulation film 110, bonding strength of the second adhesive layer 134 is smaller than bonding strength of the first adhesive layer 132. In an embodiment of the present invention, the bonding strength of the first adhesive layer 132 is between 0.4 kgf/cm and 2 kgf/cm, the bonding strength of the second adhesive layer 134 is between 5 gf/cm and 100 gf/cm, and de-bonding strength of the second adhesive layer 134 is between 5 gf/5 cm and 100 gf/5 cm. For example, when the first adhesive layer 132 is made of the epoxy resin, actual measured bonding strength of the first adhesive layer 132 is about 1 kgf/cm. When the second adhesive layer 134 is made of the acrylic acid resin, actual measured bonding strength of the second adhesive layer 134 before heating is about 14 gf/cm, and actual measured bonding strength of the second adhesive layer 134 after heating is about 37 gf/cm. De-bonding strength of the second adhesive layer 134 after heating is about 37 gf/5 cm.

In addition, the cover film 100 can further comprise a release film 140 covering on the second side of the first adhesive layer 120 to avoid adhesion of foreign materials on the second side of the first adhesive layer 120 before attaching to at least one metal conductor.

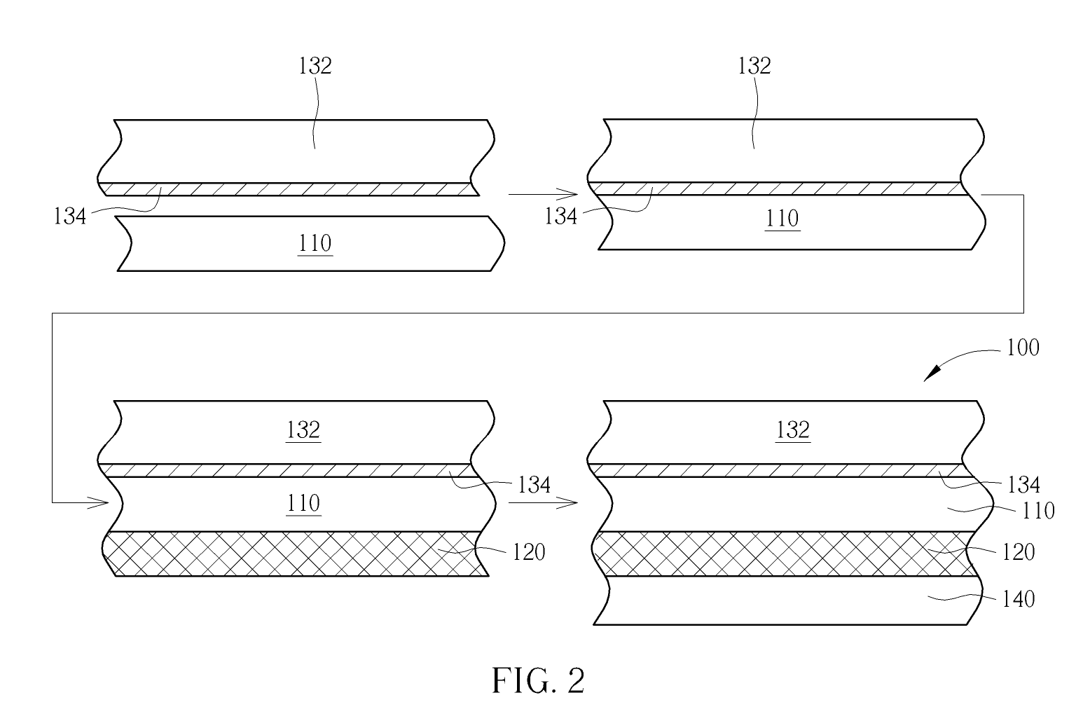

Please refer to FIG. 2 and FIG. 1. FIG. 2 is a diagram illustrating a manufacturing method of the cover film with high dimensional stability of the present invention. As shown in FIG. 2, the second adhesive layer 134 can be formed by coating an adhesive material on the supporting film 132. The insulation film 110 is further attached to the second adhesive layer 134. Then, the first adhesive layer 120 is formed by coating an adhesive material on the insulation film 110. Finally, the release film 140 is attached to the first adhesive layer 120 to form the cover film 100 with high dimensional stability of the present invention.

According to the above arrangement, when a thickness of the insulation film 110 is decreased, the supporting film 132 of the carrier 130 can still support the insulation film 110 for increasing overall mechanical strength. Therefore, when the adhesive material is applied to the insulation film 110 for forming the first adhesive layer 120, deformation of the insulation film 110 is decreased, in other words, dimensional stability of the insulation film 110 is improved.

For example, in an embodiment of the present invention, the supporting film 132 is made of the polyester resin with a thickness of 50-μm, and a 6-μm thick adhesive material is then coated on the supporting film 132 to form the second adhesive layer 134. The insulation film 110 is made of the polyimide resin with a thickness of 5-μm. After attaching the second adhesive layer 134 on the insulation film 110, a 15-μm thick adhesive material is then coated on the insulation film 110 to form the first adhesive layer 120. Finally, the release film 140 is then attached on the first adhesive layer 120 to form the cover film 100 with high dimensional stability of the present invention. According to Method A of IPC-TM-650 Method 2.2.2, dimensional stability (rate of deformation before and after removing the release film) of the insulation film 110 of the cover film 100 along a coating direction of the first adhesive layer 120 is 0.022%, and dimensional stability (rate of deformation before and after removing the release film) of the insulation film 110 of the cover film 100 perpendicular to the coating direction of the first adhesive layer 120 is 0.013%. Dimensional stability of the insulation film 110 of the cover film 100 of the present invention meets the industrial requirement within plus or minus 0.05%.

On the other hand, in a control group, the insulation film is made of the polyimide resin with a thickness of 5-μm, and then directly coated with a 15-μm thick adhesive material without support of the carrier to form an adhesive layer. Finally, a release film is attached to the adhesive layer to forma cover film of the prior art. According to Method A of IPC-TM-650 Method 2.2.2, dimensional stability (rate of deformation before and after removing the release film) of the insulation film of the cover film of the prior art along a coating direction of the adhesive layer is −0.185%, and dimensional stability (rate of deformation before and after removing the release film) of the insulation film of the cover film of the prior art perpendicular to the coating direction of the adhesive layer is −0.018%. Dimensional stability of the insulation film of the cover film of the prior art does not meet the industrial requirement within plus or minus 0.05%.

In addition, the above embodiments of the present invention are illustrated as examples, the insulation film 110, the supporting film 132, the first adhesive film 120 and the second adhesive film 134 are not limited to the thickness in the above embodiments. In an embodiment of the present invention, the thickness of the insulation film 110 is smaller than or equal to 12.5 μm. The thickness of the supporting film 132 is greater than or equal to 25 μm. When the thickness of the insulation film 110 is smaller than or equal to 12.5 μm, the insulation film 110 may easily deform, and the supporting film 132 can provide relatively stable support to the insulation film 110, so as to improve dimensional stability of the insulation film 110, and further solve the problem of aligning a positioning hole of the insulation film 110 to a positioning jig due to deformation. The thickness of the first adhesive layer 120 is greater than or equal to 10 μm. The thickness of the second adhesive layer 134 is greater than or equal to 1 μm. When the first adhesive layer 120 and the second adhesive layer 134 are made of a same adhesive material, the thickness of the second adhesive layer 134 is less than thickness of the first adhesive layer 120 so that bonding strength of the second adhesive layer 134 is smaller than bonding strength of the first adhesive layer 132.

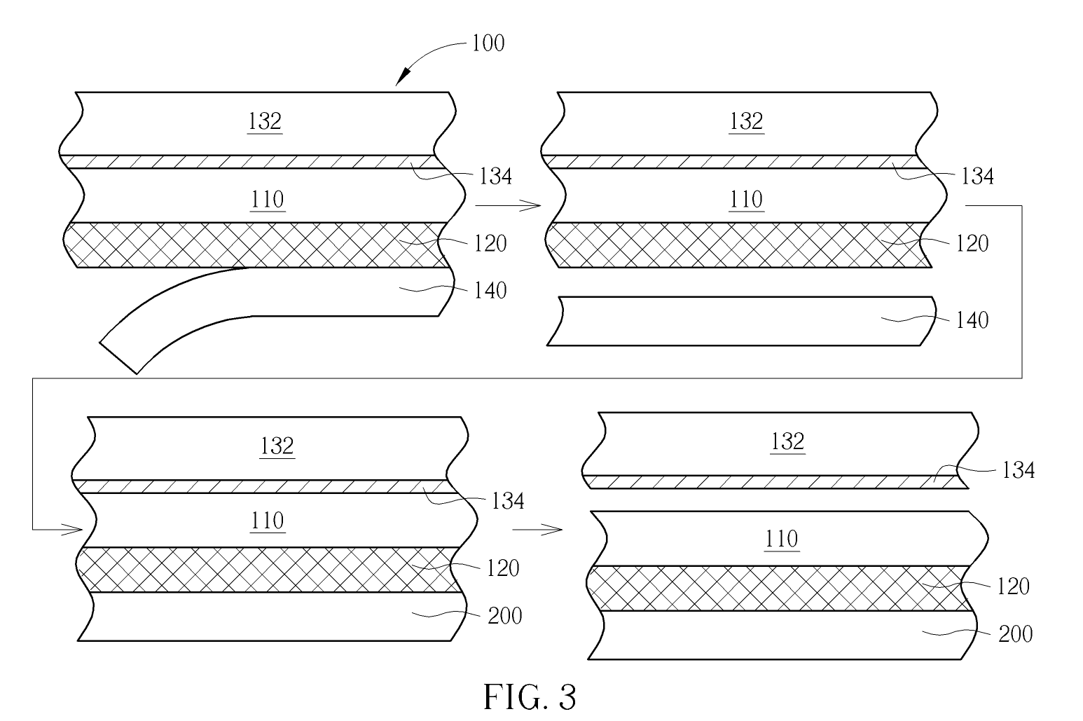

Please refer to FIG. 3. FIG. 3 is a diagram illustrating a manufacturing method of a flexible printed circuit board of the present invention. As shown in FIG. 3, when manufacturing a flexible printed circuit board, the releasing film 140 of the cover film 100 will be removed first. Then, the second side of the first adhesive layer 120 is adhered to a metal conductor 200 (e.g. metal wire) of the flexible printed circuit board. After the second side of the first adhesive layer 120 is adhered to the metal conductor 200, the carrier 130 is removed from the second surface of the insulation film 110. Moreover, the other side of the metal conductor 200 can be attached with an insulation film to further form a single layer or multilayer flexible printed circuit board.

According to the above arrangement, since the supporting film 132 of the carrier 130 can support the insulation film 110 to increase overall mechanical strength, operators can hold the insulation film 110 steady to attach the insulation film 110 to the metal conductor 200 rapidly and precisely. As a result, the cover film 100 of the present invention can improve production efficiency and yield rate of the flexible printed circuit board.

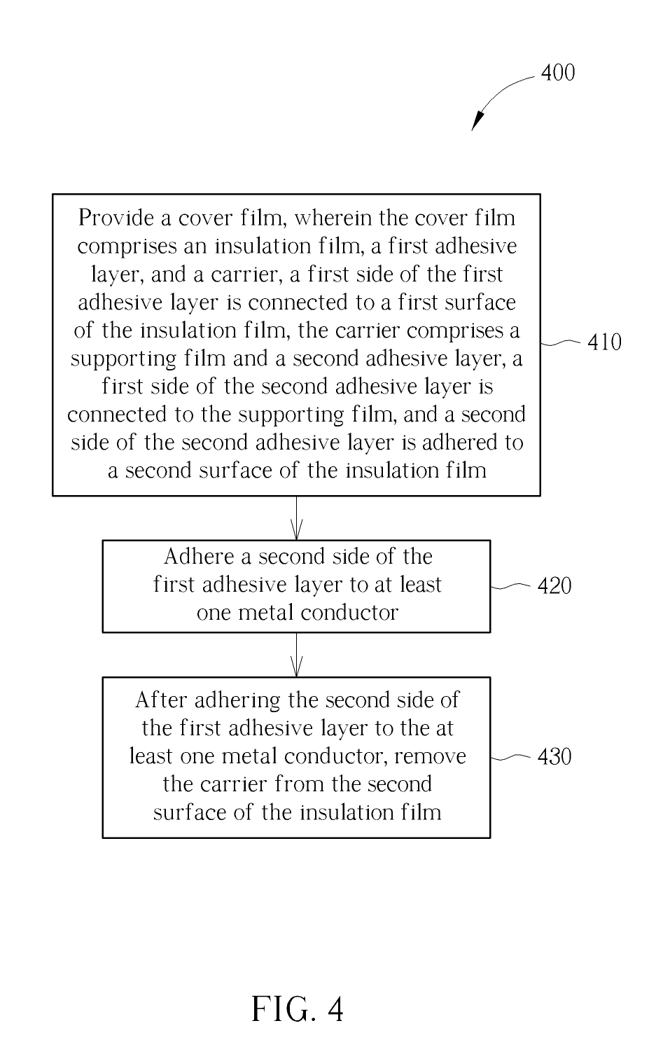

Please refer to FIG. 4. FIG. 4 is a flowchart 400 showing the manufacturing method of flexible printed circuit board of the present invention. The flowchart of the manufacturing method of the flexible printed circuit board of the present invention comprises the following steps:

Step 410: Provide a cover film, wherein the cover film comprises an insulation film, a first adhesive layer, and a carrier, a first side of the first adhesive layer is connected to a first surface of the insulation film, the carrier comprises a supporting film and a second adhesive layer, a first side of the second adhesive layer is connected to the supporting film, and a second side of the second adhesive layer is adhered to a second surface of the insulation film;

Step 420: Adhere a second side of the first adhesive layer to at least one metal conductor; and

Step 430: After adhering the second side of the first adhesive layer to the at least one metal conductor, remove the carrier from the second surface of the insulation film.

In contrast to the prior art, the cover film of the flexible printed circuit board of the present invention comprises a carrier to support the insulation film, in order to increase overall mechanical strength. Therefore, dimensional stability of the insulation film is improved to solve the deformation problem induced by thinner thickness. Moreover, when manufacturing the flexible printed circuit board, since the insulation film is supported by the carrier, operators can hold the insulation film steady to attach the insulation film to the metal conductor rapidly and precisely. As a result, the cover film of the present invention is capable of improving the production efficiency and yield rate of the flexible printed circuit board.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A cover film with high dimensional stability, comprising:
an insulation film;
a first adhesive layer, a first side of the first adhesive layer being connected to a first surface of the insulation film, and a second side of the first adhesive layer being configured to adhere to at least one metal conductor of a flexible printed circuit board; and
a carrier, comprising:
a supporting film; and
a second adhesive layer, a first side of the second adhesive layer being connected to the supporting film, and a second side of the second adhesive layer being adhered to a second surface of the insulation film;
wherein bonding strength of the second adhesive layer is smaller than bonding strength of the first adhesive layer.

2. The cover film of claim 1, wherein the carrier is removable from the second surface of the insulation film.

3. The cover film of claim 1, wherein thickness of the insulation film is smaller than or equal to 12.5 μm.

4. The cover film of claim 3, wherein thickness of the supporting film is greater than or equal to 25 μm.

5. The cover film of claim 1 further comprising a release film covering on the second side of the first adhesive layer.

6. The cover film of claim 1, wherein the insulation film is made of a material selected from a group consisting of a polyimide resin, a polyester resin, a polyethylene terephthalate resin, a polyethylene resin, a polypropylene resin, a polyvinyl chloride resin, a polystyrene resin, and a polycarbonate resin.

7. The cover film of claim 1, wherein the supporting film is made of a material selected from a group consisting of a polyimide resin, a polyester resin, a polyethylene terephthalate resin, a polyethylene resin, a polypropylene resin, a polyvinyl chloride resin, a polystyrene resin, and a polycarbonate resin.

8. The cover film of claim 1, wherein the first adhesive layer is formed by coating an acrylic acid resin, an epoxy resin, a phenol formaldehyde resin or a polyester resin on the first surface of the insulation film.

9. The cover film of claim 1, wherein the second adhesive layer is formed by coating an acrylic acid resin, a polymerized siloxanes resin, a rubber resin, an ethylene vinyl acetate (EVA) resin, a polyurethane resin or a fluorine resin on the supporting film.

10. The cover film of claim 1, wherein dimensional stability of the cover film is between −0.05% and 0.05%.

11. The cover film of claim 1, wherein bonding strength of the first adhesive layer is between 0.4 kgf/cm and 2 kgf/cm, and bonding strength of the second adhesive layer is between 5 gf/cm and 100 gf/cm.

12. A manufacturing method of a flexible printed circuit board, comprising:
providing a cover film, wherein the cover film comprises an insulation film, a first adhesive layer, and a carrier, a first side of the first adhesive layer is connected to a first surface of the insulation film, the carrier comprises a supporting film and a second adhesive layer, a first side of the second adhesive layer is connected to the supporting film, and a second side of the second adhesive layer is adhered to a second surface of the insulation film;
adhering a second side of the first adhesive layer to at least one metal conductor; and
after adhering the second side of the first adhesive layer to the at least one metal conductor, removing the carrier from the second surface of the insulation film.

13. The manufacturing method of claim 12, wherein the cover film further comprises a release film covering on the second side of the first adhesive layer, the method further comprises:
removing the release film before adhering the second side of the first adhesive layer to the at least one metal conductor.
